(19) United States
(12) Patent Application Publication
(10) Pub. No.: US 2025/0297396 A1
(43) Pub. Date: Sep. 25, 2025

(54) ELECTRODEPOSITED COPPER FOIL WITH A PREFFERED ORIENTATION OF (200) CRYSTAL PLANE AND APPLICATIONS THEREOF

(71) Applicant: DUPONT ELECTRONICS, INC., Wilmington, DE (US)

(72) Inventors: SHIH-CHING LIN, HSINCHU (TW); YA-MEI LIN, HSINCHU (TW)

(21) Appl. No.: 19/071,015

(22) Filed: Mar. 5, 2025

Related U.S. Application Data
(60) Provisional application No. 63/567,028, filed on Mar. 19, 2024.

(51) Int. Cl. C25D 1/04; C25D 1/20; H05K 1/03

(52) U.S. Cl. CPC C25D 1/04; C25D 1/20; H05K 1/0393; H05K 2201/0338

(57) ABSTRACT

Disclosed is an electrodeposited copper foil having a preferred orientation of (200) crystal plane after heat treatment. The electrodeposited copper foil after heat treatment has a microstructure similar to that of a rolled annealed copper foil and exhibits excellent mechanical properties. Also disclosed are a manufacturing method of the electrodeposited copper foil, and applications thereof. The applications include flexible copper-clad laminates, printed circuit boards, and electronic devices made therefrom.

### FIELD OF THE INVENTION

The present application relates to an electrodeposited copper foil having a preferred orientation of (200) crystal plane after heat treatment, a manufacturing method thereof, and flexible copper-clad laminates, printed circuit boards, and electronic devices made therefrom.

### BACKGROUND OF THE INVENTION

Traditionally, copper foils may be classified into two major categories according to the manufacturing manners thereof, i.e., rolled annealed (RA) copper foils and electrodeposited (ED) copper foils. RA copper foils are made from copper sheet as raw materials by subjecting it to a series of cold and hot rolling processes using rollers followed by processes such as annealing to roll into thin copper foils gradually, and finally forming copper foils with thickness generally between 6 and 70 μm. On the other hand, ED copper foils are made from copper particles or copper wires as raw materials by dissolving them in a solution of sulfuric acid to form a solution of copper sulfate, then performing electroplating with direct current to reduce the copper ions in the solution of copper sulfate to copper atoms which then deposit on the surface of a negative electrode, and finally forming copper foils with thickness between 6 and 70 μm. The thickness of 6 to 70 μm reference to aforementioned copper foils stands for the specification commonly used, and copper foils of other thickness may be prepared with various thickness by controlling the rolling process or adjusting parameters of the electroplating process.

Although RA copper foils and ED copper foils are prepared with different methods, the base copper foils produced by these methods (i.e., excluding the surface-treated portion) have nearly the same chemical compositions, which is pure copper with purities of more than 99.9%. But RA copper foils have mechanical properties greatly differing from electrodeposited copper foils, e.g., tensile strength, elongation, bending resistance, etc. The main reason is that the RA copper foils have microstructure of grain arrangement changed after thermal processes (e.g., oven baked copper foils, or copper foils after undergoing laminating or coating with resin, etc.).

Whether being a RA copper foil or an electrodeposited copper foil, its grain structure is a polycrystalline structure (non-uniform sizes with larger and smaller grains) with directionality, and the microstructure or texture may be determined and analyzed by X-ray diffraction (XRD) and electron backscatter diffraction (EBSD). Crystallographic planes are expressed with three Miller indexes such as (hkl). Since XRD diffraction peaks are correlated with the distance between atoms, relative positions, and numbers of atoms in unit cells, according to the selection rule, the (hkl) representing a crystal plane with a crystalline structure of face-centered cubic (FCC) must be all odd numbers or all even numbers, so that there may be crystal planes including but are not limited to (200), (220), (111), (311), etc. in the crystal plane orientation distributions obtained by XRD analysis. The signals of EBSD are derived from the Kikuchi pattern generated by diffraction kinematic, so that the grain orientation is characterized by {001}, {101} and {111} crystal plane family. The advantage of EBSD analysis over XRD analysis is the capability to obtain a measurement on a smaller grain size. Although the results of two analytic methods, XRD and EBSD, are different, they still have reference values on the characterization in the preferred orientation and grain orientation distribution of the electrodeposited copper foil.

Although RA copper foil and ED copper foil have similar chemical compositions, these two categories of copper foils after heat treatment are quite different in grain orientation distribution and grain sizes, consequently, they have different mechanical properties (e.g., elongation, ductility) and electric properties (e.g., volume resistivity, conductor loss). This also results in that for some special applications a RA copper foil must be employed, for example, RA copper foils with a high elongation and a high ductility are used in manufacturing high-frequency high-speed printed circuit boards to improve the thermal stability of the product and avoid deformation and warping. However, due to the high price of RA copper foils, use of ED copper foils in manufacturing printed circuit boards have the advantage of lowering the production cost.

Based on the aforementioned disadvantages of RA copper foils and ED copper foils, one purpose of the present application is to provide an ED copper foil with a preferred orientation of (200) crystal plane. Another purpose of the present application is to provide a manufacturing method and applications thereof. The applications comprise flexible copper-clad laminates, printed circuit boards, and electronic devices manufactured therefrom.

### SUMMARY OF THE INVENTION

The present application provides an electrodeposited copper foil with a preferred orientation of (200) crystal plane after heat treatment, wherein
the electrodeposited copper foil prior to heat treatment has a grain orientation ratio of 20% or less on the (200) crystal plane as determined by XRD analysis, and a grain orientation ratio of less than 20% on the {001} crystal plane family as determined by EBSD analysis;
the electrodeposited copper foil after heat treatment has a grain orientation ratio of 50% or more on the (200) crystal plane as determined by XRD analysis, and a grain orientation ratio of 20% or more on the {001} crystal plane family as determined by EBSD analysis; and the heat treatment is conducted by heating at 200° C. for 2 hours.

The present application also provides a method for manufacturing the present electrodeposited copper foil, which comprises:
i) providing an electrolytic solution at a temperature of 20° C. to 55° C. in an electrolytic cell;
ii) applying an electric current at a current density of 30 A/dm² to 100 A/dm² to an anode plate and a rotating cathode drum that are spaced apart from each other in the electrolytic solution;
iii) obtaining a copper foil on the rotating cathode drum by electrodeposition; and
iv) separating the copper foil obtained from step iii);
   wherein
   the electrolytic solution comprises:
120 g/L to 450 g/L of copper sulfate;
30 g/L to 140 g/L of sulfuric acid;
0.01 ppm to 5.00 ppm of chloride ion; and
0.01 ppm to 2.50 ppm of at least one additive.

The present application additionally provides a flexible copper-clad laminate, comprising:
the present electrodeposited copper foil or an electrodeposited copper foil prepared by the present method, and
a dielectric layer provided on at least one surface of the electrodeposited copper foil; wherein
the electrodeposited copper foil has a grain orientation ratio of 50% or more on the (200) crystal plane as determined by XRD analysis, and a grain orientation ratio of 20% or more on the {001} crystal plane family as determined by EBSD analysis;
the dielectric layer has a thickness of 5 μm to 100 μm; and
the dielectric layer is composed of at least one layer of a polymeric material having a thermal decomposition temperature (1%) of 260° C. or higher.

The present application further provides a printed circuit board that is manufactured from the present flexible copper-clad laminate.

The present application still further provides an electronic device comprising the present printed circuit board.

### BRIEF DESCRIPTION OF THE DRAWINGS

FIGS. 1A and 1B show the grain orientation distribution graphs of the M sides of two copper foils obtained by XRD analysis. The specimen for FIG. 1A is the RA copper foil of Comparative Example 1 of the present application; and the specimen for FIG. 1B is the ED copper foil of Comparative Example 3 of the present application.

FIGS. 2A and 2B show the grain size photographs of the cross-sections of two copper foils obtained by EBSD analysis. The specimen for FIG. 2A is the RA copper foil of Comparative Example 1 of the present application; and the specimen for FIG. 2B is the ED copper foil of Comparative Example 3 of the present application.

FIG. 3 shows one embodiment of the manufacture process for the electrodeposited copper foil of the present application.

FIGS. 4A and 4B, respectively, show the grain orientation distribution graph obtained by XRD analysis of an embodiment of the present ED copper foil, and the grain size photograph of the cross-section of the copper foil obtained by EBSD analysis. The ED copper foil is a specimen of Example 6 of the present application.

### DETAILED DESCRIPTION OF THE EMBODIMENTS

All publications, patent applications, patents and other references mentioned herein, if not otherwise indicated, are explicitly incorporated by reference herein in their entirety for all purposes as if fully set forth.

Unless otherwise defined, all technical and scientific terms used herein have the same meaning as commonly understood by one of ordinary skill in the art to which this application belongs. In case of conflict, the present specification, including definitions, will prevail.

Unless stated otherwise, all percentages, parts, ratios, etc., are by weight.

As used herein, the term “composed of” has the same meaning with “comprising.” As used herein, the terms “comprises,” “comprising,” “includes,” “including,” “has,” “having,” “contains” or “containing,” or any other variation thereof, are intended to cover a non-exclusive inclusion. For example, a composition, process, method, article, or apparatus that comprises a list of elements is not necessarily limited to only those elements but may include other elements not expressly listed or inherent to such composition, process, method, article, or apparatus.

The transitional phrase “consisting of” excludes any element, step, or ingredient not specified. If in the claim, such a phrase would close the claim to the inclusion of materials other than those recited except for impurities ordinarily associated therewith. When the phrase “consisting of” appears in a clause of the body of a claim, rather than immediately following the preamble, it limits only the element set forth in that clause; other elements are not excluded from the claim as a whole.

The transitional phrase “consisting essentially of” is used to define a composition, method or apparatus that includes materials, steps, features, components, or elements, in addition to those literally discussed, provided that these additional materials, steps, features, components, or elements do not materially affect the basic and novel characteristic(s) of the claimed application. The term “consisting essentially of” occupies a middle ground between “comprising” and “consisting of”.

The term “comprising” is intended to include embodiments encompassed by the terms “consisting essentially of” and “consisting of”. Similarly, the term “consisting essentially of” is intended to include embodiments encompassed by the term “consisting of”.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. For example, when a range of “1 to 5” is recited, the recited range should be construed as including ranges “1 to 4”, “1 to 3”, “1-2”, “1-2 & 4-5”, “1-3 & 5”, and the like. Where a range of numerical values is recited herein, unless otherwise stated, the range is intended to include the endpoints thereof, and all integers and fractions within the range.

Further, unless expressly stated to the contrary, “or” refers to an inclusive “or” and not to an exclusive “or”. For example, a condition A “or” B is satisfied by any one of the following: A is true (or present) and B is false (or not present), A is false (or not present) and B is true (or present), and both A and B are true (or present).

“Mol %” or “mole %” refers to mole percent.

When referring to a grain orientation ratio on a specific crystal plane or crystal plane family, this means the proportion of the indicated specific crystal plane or crystal plane family relative to the sum of all crystal planes.

“Twin grain boundary” refers to the boundary of two adjacent grains which present certain symmetrical features. Twinning for copper usually takes place at an angle of 60 degree. When referring to a twin grain boundary ratio, this means the proportion of the total length of the twin grain boundary relative to the total length of all grain boundaries.

The embodiments of the present application as described in the summary comprises any other embodiments described herein, may be combined in any manner, and the description for variables in the embodiments is not only for the electrodeposited copper foil of the present application but also for a flexible copper-clad laminate comprising the electrodeposited copper foil.

The present application will be described in detail hereinunder.

The present application provides an electrodeposited copper foil which after heat treatment has a preferred orientation of (200) crystal plane, wherein the electrodeposited copper foil prior to heat treatment (i.e., untreated) has a grain orientation ratio of 20% or less on the (200) crystal plane as determined by XRD analysis; and a grain orientation ratio of less than 20% on the {001} crystal plane family as determined by EBSD analysis; the electrodeposited copper foil after heat treatment has a grain orientation ratio of 50% or more on the (200) crystal plane as determined by XRD analysis; and a grain orientation ratio of 20% or more on the {001} crystal plane family as determined by EBSD analysis; and the heat treatment is conducted by heating at 200° C. for 2 hours.

In one embodiment, the electrodeposited copper foil of the present application prior to heat treatment has a preferred orientation of (111) crystal plane; and after heat treatment has a preferred orientation of (200) crystal plane, and the grain orientation ratio on the (200) crystal plane is 50% or more.

In the present application, the electrodeposited copper foil prior to heat treatment has a grain orientation ratio of 20% or less, particularly 5% to 20%, on the (200) crystal plane as determined by XRD analysis. For example, the grain orientation ratio on the (200) crystal plane prior to heat treatment can be 5%, 7.5%, 10%, 12.5%, 15%, 17.5%, or 20%, or within a range between any two of the values described herein. In addition, the electrodeposited copper foil prior to heat treatment has a grain orientation ratio of less than 20%, particularly 5% to 20%, on the {001} crystal plane family as determined by EBSD analysis. For example, the grain orientation ratio on the {001} crystal plane family prior to heat treatment can be 5%, 7.5%, 10%, 12.5%, 15%, 17.5%, or 19.5%, or within a range between any two of the values described herein.

In the present application, the electrodeposited copper foil after heat treatment has a grain orientation ratio of 50% or more, or 55% or more, or 60% or more, particularly 50% to 90%, on the (200) crystal plane as determined by XRD analysis. For example, the grain orientation ratio on the (200) crystal plane after heat treatment can be 50%, 55%, 60%, 65%, 70%, 75%, 80%, 81%, 89% or 90% or within a range between any two of the values described herein. In addition, the electrodeposited copper foil after heat treatment has a grain orientation ratio of 20% or more, particularly 20% to 45%, on the {001} crystal plane family as determined by EBSD analysis. For example, the grain orientation ratio on the {001} crystal plane family after heat treatment can be 20%, 25%, 30%, 35%, 40%, or 45%, or within a range between any two of the values described herein.

In one embodiment, the electrodeposited copper foil of the present application prior to heat treatment has an average grain size of less than 1.0 μm, particularly 0.5 μm to 1.0 μm, more particularly 0.8 μm to 1.0 μm; and the average grain size is determined by EBSD analysis.

In one embodiment, the electrodeposited copper foil of the present application prior to heat treatment has a twin grain boundary ratio of 30% or less, particularly 20% to 30%, more particularly 23% to 28%; and the twin grain boundary ratio is determined by EBSD analysis.

In one embodiment, the electrodeposited copper foil of the present application after heat treatment has an average grain size of 2.0 μm or more, or 2.5 μm or more, or 3.0 μm or more, particularly 2.0 μm to 5.5 μm, more particularly 2.0 μm to 4.7 μm; and the average grain size is determined by EBSD analysis.

In one embodiment, the electrodeposited copper foil of the present application after heat treatment has a twin grain boundary ratio of 50% or more, or 55% or more, or a twin grain boundary ratio 60% or more, particularly 50% to 85%, more particularly 55% to 80%; and the twin grain boundary ratio is determined by EBSD analysis.

In one embodiment, the electrodeposited copper foil of the present application has a thickness of 3.0 μm to 300 μm, or 3.5 μm to 150 μm, or 4.5 μm to 75 μm, or 5.0 μm to 35 μm.

In one embodiment, the electrodeposited copper foil of the present application prior to heat treatment has an M side with a surface roughness (Sz) of 3.0 μm or less, or 2.5 μm or less, or 2.0 μm or less, particularly 1.5 μm to 3 μm, more particularly 2.0 μm to 2.8 μm. In addition, the applicant of the present application found that the electrodeposited copper foil of the present application prior to heat treatment has an M side with a surface roughness that is similar to the surface roughness after heat treatment, i.e., without obvious difference.

In one embodiment, the electrodeposited copper foil of the present application prior to heat treatment has an elongation of less than 5%, or less than 4.5%, particularly 3% to 4.8%, more particularly 3.5% to 4.5%.

In one embodiment, the electrodeposited copper foil of the present application after heat treatment has an elongation of 5% or more, or 6% or more, or 7% or more, particularly 5% to 18%, more particularly 6.5% to 15%.

In one embodiment, the electrodeposited copper foil of the present application after heat treatment has a tensile strength of 15 Kgf/mm² or more, or 17 Kgf/mm² or more, or 19 Kgf/mm² or more.

In one embodiment, the electrodeposited copper foil of the present application after heat treatment has a tensile strength of 25 Kgf/mm² or less, or 24 Kgf/mm² or less, or 23 Kgf/mm² or less.

Another purpose of the present application is to provide a method for manufacturing the electrodeposited copper foil of the present application. The method is characterized in maintaining a high current density under a production condition, selecting a suitable additive and controlling its amount in an electrolytic solution, and adjusting each parameter in the electroplating step, thereby preparing an electrodeposited copper foil which after heat treatment has a preferred orientation of (200) crystal plane. The method comprises:
i) providing a formulated electrolytic solution at a temperature of 20° C. to 55° C. in an electrolytic cell;
ii) applying an electric current at a current density of 30 A/dm² to 100 A/dm² to an anode plate (i.e., the positive electrode) and a rotating cathode drum (i.e., the negative electrode) that are spaced apart from each other in the electrolytic solution;
iii) obtaining a copper foil on the rotating cathode drum by electrodeposition; and
iv) separating the copper foil obtained from step iii);
   wherein
   the electrolytic solution comprises:
120 g/L to 450 g/L of copper sulfate;
30 g/L to 140 g/L of sulfuric acid;
0.01 ppm to 5.00 ppm of chloride ion; and
0.01 ppm to 2.50 ppm of at least one additive.

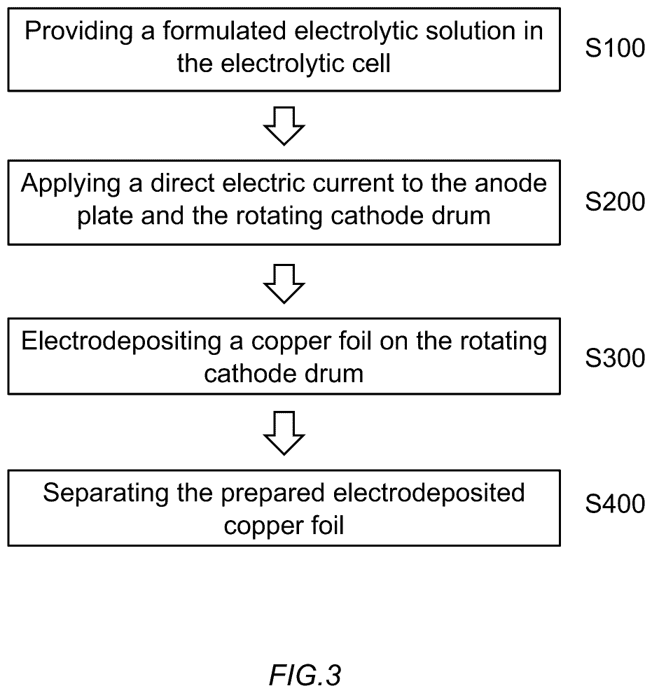

FIG. 3 is a flowchart of one embodiment according to the method of the present application. With reference to FIG. 3, the method comprises firstly performing Step S100: providing a formulated electrolytic solution into an electrolytic cell; then performing Step S200: applying a direct electric current to the anode plate and the rotating cathode drum; thereafter performing Step S300: electrodepositing a copper foil on the cathode drum; and finally performing Step S400: separating the prepared electrodeposited copper foil. The control conditions of the electrodeposition comprise: the temperature of the electrolytic solution and the current density of the applied direct current.

The prepared electrodeposited copper foil has two surfaces. During the manufacturing process, the surface contacting the drum is referred to as the “drum side” of the copper foil; and the surface opposite to the drum side, i.e., the surface facing the electrolytic solution, is referred to as the “deposit side”. Generally, the “drum side” of a copper foil is its shiny side (S side), and the “deposit side” is the matte side (M side).

In the method of the present application, the temperature of the electrolytic solution generally ranges between 20° C. and 55° C., preferably between 30° C. and 50° C.

In the method of the present application, the electrodeposition may be carried out by applying a direct current at a current density ranging from 30 A/dm² to 100 A/dm². Generally, the electrodeposition is carried out at a current density of 60 A/dm², or 70 A/dm², or 80 A/dm². The copper foil may be yielded at 16 μm/min or more, the yield may satisfy the standards of an industrial high-speed production, especially when the electrodeposition is carried out at 60 A/dm² or more with a suitable rotary rate of the cathode drum.

In the method of the present application, the electrolytic solution comprises copper sulfate, sulfuric acid, chloride ions, and at least one additive. The copper sulfate (as the copper ion source) and the sulfuric acid in the electrolytic solution may be commercially available from various sources and may be used without further purification.

In one embodiment, the amount of copper sulfate in the electrolytic solution is 120 g/L to 450 g/L, or 180 g/L to 400 g/L, or 240 g/L to 350 g/L, based on the total volume of the electrolytic solution.

In one embodiment, the amount of sulfuric acid in the electrolytic solution is 30 g/L to 140 g/L, or 50 g/L to 130 g/L, or 70 g/L to 120 g/L, based on the total volume of the electrolytic solution.

The chloride ion source may be copper chloride or hydrochloric acid. The chloride ion sources may be commercially available and may be used without further purification.

In one embodiment, the amount of chloride ions in the electrolytic solution is 0.01 ppm to 5.00 ppm, or 0.05 ppm to 2.50 ppm, or 0.10 ppm to 1.00 ppm, based on the total weight of the electrolytic solution.

The additive suitable for use in the electrolytic solution includes gelatin, animal glue, cellulose, nitrogen-containing cationic polymer, or a combination thereof. There is no special limitation on the additives used so long as the electrodeposited copper foil prepared after heat treatment has a preferred orientation of (200) crystal plane. The additives aforementioned may be used alone or in a combination as desired. In one embodiment, the additive is a nitrogen-containing cationic polymer.

In one embodiment, the additive is a nitrogen-containing cationic polymer, and the nitrogen-containing cationic polymer has a weight-average molecular weight of from 500 g/mole to 12,000 g/mole.

In another embodiment, the nitrogen-containing cationic polymer is a reaction product of a diamine of Formula (I) or an imidazole of Formula (II) with an epoxide of Formula (III) or a diepoxide of Formula (IV) in 1:1 molar ratio:

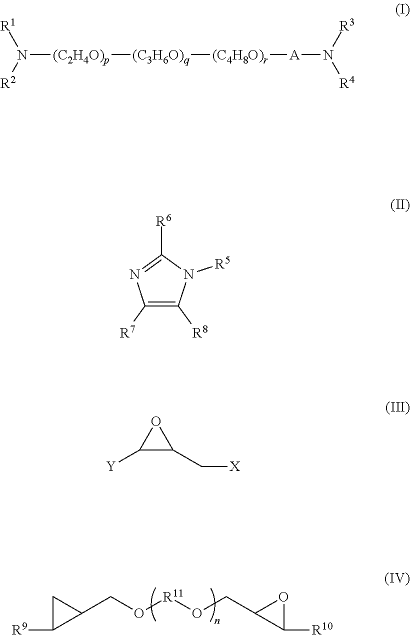

wherein
each of R¹, R², R³, and R⁴ is independently H or C₁-C₃ alkyl;
each of R⁵, R⁶, R⁷, and R⁸ is independently H or C₁-C₆ alkyl, and R⁷ and R⁸ are optionally linked to each other to form a saturated ring;
R⁹ and R¹⁰ are each independently H or C₁-C₄ alkyl;
R¹¹ is a divalent linking group selected from C₂-C₈ alkylene, C₅-C₁₀ cycloalkylene, and C₁-C₄ alkylene-C₅-C₁₀ cycloalkylene, where R¹¹ is optionally substituted with C₁-C₄ alkyl or —OH;
A is a divalent linking group selected from C₂-C₈ alkylene, C₅-C₁₀ cycloalkylene, C₁-C₄ alkylene-C₅-C₁₀ cycloalkylene-C₁-C₄ alkylene, C₆-C₂₀ arylene, and C₁-C₄ alkylene-C₆-C₂₀ arylene-C₁-C₄ alkylene, and where A is optionally substituted with C₁-C₄ alkyl or —OH;
Y is H or C₁-C₄ alkyl;
X is halogen;
each of p, q, and r is independently an integer of 0 to 10; and
n is an integer from 1 to 20.

In the method of the present application, the amount of the additive in the electrolytic solution depends on the specific additive selected, the chloride ion concentration in the electrolytic solution, and the current density applied. In the method of the present application, the amount of the additive in the electrolytic solution generally is 0.01 ppm to 2.50 ppm, based on the total weight of the electrolytic solution.

In one embodiment, the amount of the additive in the electrolytic solution is 0.01 ppm to 2.50 ppm, or 0.05 ppm to 1.50 ppm, or 0.10 ppm to 0.50 ppm, based on the total weight of the electrolytic solution.

In the method of the present application, the electrolytic solution may additionally comprise one or more other additives, such as an inhibitor or a crystal orientation modifier, etc. These other additives may be used alone or in a combination as desired. Other additives may be present generally in a small amount (i.e., below 5 ppm) so long as they don't interfere with the functional properties of the electrodeposited copper foil of the present application.

The electrodeposited copper foil prepared by the method of the present application is referred to as a base foil, which after a suitable surface treatment, such as copper foil surface treatment process commonly used, including processes of acid pickling, roughening, heat-resistant layer electroplating, antioxidation layer electroplating, silane treatment, etc., is suitable for preparing a flexible copper-clad laminate. Depending on the application of the copper foil, the surface treatment processes may be applied on one side or both sides of the base foil. When an electrodeposited copper foil is included in a flexible copper-clad laminate, the side of the copper foil contacting the dielectric layer is referred to as the “lamination side”, and the side opposite to the “lamination side” is referred to as the “resist side.” In order to increase the adhesion between the copper foil and the dielectric layer, the surface treatment process aforementioned, for example, roughening (i.e., forming copper nodules by electroplating) or silane treatment, etc., is applied to at least the lamination side of the copper foil. When the roughening copper nodules are adhered to the M side of the base foil, the copper foil is generally referred to as a normally treated copper foil. When the roughening copper nodules are adhered to the S side of the base foil, the electrodeposited copper foil is referred to as a reversed treated copper foil (RTF).

Since the grain sizes and the preferred grain orientation of the electrodeposited copper foil of the present application are related to the microstructure of the base foil, there is no impact on various excellent properties exhibited by the base foil regardless the roughening copper nodules are adhered to the S side or M side.

### Flexible Copper-Clad Laminates

Another purpose of the present application is to provide a flexible copper-clad laminate (FCCL), comprising:
the present electrodeposited copper foil or an electrodeposited copper foil prepared by the present method, and a dielectric layer provided on at least one surface of the electrodeposited copper foil; wherein
the electrodeposited copper foil has a grain orientation ratio of 50% or more on the (200) crystal plane as determined by XRD analysis, and a grain orientation ratio of 20% or more on the {001} crystal plane family as determined by EBSD analysis;
the dielectric layer has a thickness of 5 μm to 100 μm; and
the dielectric layer is composed of at least one layer of a polymeric material having a thermal decomposition temperature (1%) of 260° C. or higher.

The flexible copper-clad laminate of the present application may be a single-sided FCCL or a double-sided FCCL.

In one embodiment of the present application, the single-sided FCCL or double-sided FCCL contains a dielectric layer with a thickness of 5.0 μm to 100 μm, or 10 μm to 75 μm, or 15 μm to 60 μm, or 20 μm to 50 μm. Depending on the specific uses of the flexible copper-clad laminate of the present application, the ratio of the thickness of the electrodeposited copper foil to the thickness of the dielectric layer ranges from 2:1 to 1:10.

In one embodiment of the present application, the electrodeposited copper foil in the present single-sided FCCL or double-sided FCCL uses its S side as the lamination side to contact with the dielectric layer, and the S side of the electrodeposited copper foil has been roughened.

The flexible copper-clad laminate of the present application is prepared by a method comprising: providing the present electrodeposited copper foil or an electrodeposited copper foil manufactured by the present method; and coating or laminating at least one layer of polymer material or a precursor thereof to form a dielectric layer on at least one surface of the electrodeposited copper foil. The process temperature used in the method above may be up to 260° C. to 350° C.; therefore, the polymer material forming the dielectric layer is required to be able to withstand high temperature for several hours. A suitable polymer material has a thermal decomposition temperature (1%) of 260° C. or above, or 300° C. or above, or 340° C. or above.

In one embodiment, the dielectric layer included in the flexible copper-clad laminate of the present application is composed of at least one layer of a polymer material which has a thermal decomposition temperature (1%) of 260° C. or above, or 300° C. or above, or 340° C. or above.

One skilled in the art can select a suitable polymer material to form the dielectric layer in the flexible copper-clad laminate of the present application with the abovementioned characteristics for the desired applications. Suitable polymer material comprises polyimides (PI), liquid crystal polymers, or fluorine-based polymers such as poly(tetrafluoroethylene). In one embodiment, the dielectric layer is composed of polyimide.

In one embodiment, in the flexible copper-clad laminate of the present application, the polymer material forming the dielectric layer is a polyimide, a liquid crystal polymer, or a fluorine-based polymer.

### Polyimides

When the dielectric layer is composed of polyimide, precursors of the polyimide is the corresponding polyamic acid which may be prepared by any methods known by one skilled in the art. The steps comprise adding a diamine component, a dianhydride component to a solution, and mixing and stirring at a suitable temperature to obtain a polyimide precursor, i.e., a polyamic acid. The polyimide precursor may be cast on a base film, and then baked and cured at an elevated temperature to provide a polyimide film. A single-sided copper-clad laminate of the present application may be obtained when the aforementioned base film is the surface-treated copper foil of the present application.

Suitable diamine component may be an aromatic diamine selected from the group consisting of p-phenylene diamine (PPD), m-phenylene diamine (MPD), 2,5-dimethyl-1,4-phenylene diamine (DPX), 2,4-diaminotoluene, 2,5-diaminotoluene, 2,6-diaminotoluene, trifluoromethyl-2,4-diaminobenzene, trifluoromethyl-3,5-di-aminobenzene, 4,4′-diaminobiphenyl, 2,2′-dimethyl-4,4′-diaminobiphenyl, 3,3′-di-methyl-4,4′-diaminobiphenyl, 2,2′-bis(trifluoromethyl)benzidine (TFMB), 2,2-bis-(4-aminophenyl)propane, 2,2′-bis(4-aminophenyl)hexafluoropropane (6F diamine), 4,4′-diaminobenzophenone, 4,4′-diaminodiphenylmethane (MDA), 4,4′-diamino-diphenyl ether (ODA), 3,4′-diaminodiphenyl ether, 4,4′-di-aminobenzanilide, 2-methoxy-4,4′-diaminobenzanilide, 1,2-bis-(4-aminophenoxy)benzene, 1,3-bis-(4-aminophenoxy)-benzene, 1,4-bis-(4-aminophenoxy)benzene, 1,2-bis-(3-amino-phenoxy)benzene, 1,3-bis-(3-aminophenoxy)benzene, 1,4-bis-(3-aminophenoxy)-benzene, 1-(4-aminophenoxy)-3-(3-aminophenoxy)benzene, 1-(4-aminophenoxy)-4-(3-aminophenoxy)benzene, 4,4-bis(aminophenoxy)biphenyl (BAPB), 2,2-bis-(4-[4-aminophenoxy]phenyl)propane (BAPP), 4-amino-phenyl-3-aminobenzoate, 4-aminophenyl-4-amino-benzoate, and N,N-bis-(4-aminophenyl)aniline, and combinations thereof.

A suitable dianhydride component may be an aromatic dianhydride selected from the group consisting of pyromellitic dianhydride (PMDA), 3,3′,4,4′-biphenyltetracarboxylic dianhydride (BPDA), 2,2′,3,3′-biphenyltetracarboxylic dianhydride, 2,3,3′,4′-biphenyl-tetracarboxylic dianhydride, 2,2′-bis[4-(4-aminophenoxy)phenyl]tetracarboxylic dianhydride, 3,3′,4,4′-benzophenonetetracarboxylic dianhydride (BTDA), 2,2′,3,3′-benzo-phenonetetracarboxylic dianhydride, 2,3,3′,4′-benzophenonetetracarboxylic dianhydride, bis-2,5-(3′,4′-dicarboxydiphenyl ether), 4,4′-oxydiphthalic anhydride (ODPA), bis(3,4-dicarboxyphenyl)sulfide dianhydride, bisphenol A dianhydride (BPADA), bisphenol S dianhydride, 2,2-bis-(3,4-dicarboxyphenyl)-1,1,1,3,3,3-hexafluoropropane dianhydride (6FDA), and a combination thereof. Noted that the dianhydride(s) constituting the dianhydride component may be in form of a dianhydride, or in forms of a tetra-acid or a diester acid halide. However, in some embodiments, the dianhydride component in form of a dianhydride is preferred since it is more reactive than corresponding acid or ester.

Examples of the solvent used in the polymerization of polyamic acid include dimethylacetamide, N-methyl pyrrolidone, 2-butanone, diglyme, or xylene, which may be used alone or in a combination of two or more solvents.

The commercially available low dielectric polyimide film suitable for the present application comprises Kapton® from DuPont Electronics, Inc.; APICAL™, Pixeo™ BP from Kaneka; or UPILEX® from Ube.

The flexible copper-clad laminate of the present application may be manufactured by laminating a thermoplastic film formed from the aforementioned polymer material onto at least one treated surface of a surface-treated copper foil. Alternatively, the flexible copper-clad laminate of the present application may be manufactured by applying a coating composition containing the aforementioned polymer material or the precursor thereof onto a treated surface of a surface-treated copper foil of the present application. Depending on the choice of the polymer material for forming the dielectric layer, the coating composition may contain a suitable solvent or a solvent system. The dielectric layer may be formed by using any appropriate preparation methods readily implemented by one skilled in the art.

The coating composition forming the dielectric layer may be applied by various methods that are well known in the art, including spray coating, curtain coating, knife over roll coating, air knife coating, slit die coating, direct gravure printing, reverse gravure printing, offset gravure printing, or roll coating.

The dielectric layer in the flexible copper-clad laminate of the present application is preferably prepared by coating a polymer material containing solution/dispersion medium directly due to the ease of controlling the thickness and physical properties. The dielectric layer may be formed by a single layer alone, but preferably be formed of a plurality of layers considering the adhesion between the dielectric layer and the electrodeposited copper foil of the present application.

As described above, the dielectric layer may be formed by a single layer or a plurality of layers. For a single-sided FCCL having a single polyimide layer, the polyimide precursor may be applied onto the surface-treated copper foil by direct casting; for a plurality of polyimide layers, it may be formed by applying other polyamic acid solutions sequentially onto the polyamic acid solution formed of different constituting components. When the dielectric layer composed of polyimide is formed by a plurality of layers, a polyimide precursor of the same composition may be used twice or multiple times.

In one embodiment, for a double-sided FCCL having a plurality of polyimide layers as the dielectric layer, the polyimide layers with a multi-layered structure can be firstly formed and then placed on the first and second surfaces of the electrodeposited copper foil, following by lamination simultaneously or sequentially.

After coating, the solvent or mixed solvents may be removed by heating in an oven at a temperature ranging from 100° C. to 200° C. The heating temperature and duration in the oven will depend on the solvent(s) used and the thickness of the coating layer.

The process parameters used for preparing the flexible copper-clad laminate of the present application, such as temperature, pressure, and time, etc., generally depend on the material properties of the substrate and the preparation method. One skilled in the art can determine suitable process parameters accordingly.

In some embodiments, the flexible copper-clad laminate of the present application is manufactured by lamination.

In some embodiments, the lamination is performed at a temperature ranging from 200° C. to 400° C., or from 300° C. to 370° C.; under a pressure ranging from 0.5 MPa to 10.0 MPa, or from 1.0 MPa to 5.0 MPa; and for a duration ranging from 30 minutes to 300 minutes, or from 60 minutes to 240 minutes.

Regardless of whether the dielectric layer in the flexible copper-clad laminate of the present application is formed by a coating method or a laminating method, the aforementioned method comprises a corresponding heating process, therefore, the electrodeposited copper foil of the present application may be used in manufacturing of the flexible copper-clad laminate directly without prior heat treatment. Furthermore, comparing with a flexible copper-clad laminate employing a conventional ED copper foil, the present flexible copper-clad laminate exhibits similar grain sizes and grain orientation distribution to that of a FCCL comprising a RA copper foil due to the ED copper foil comprised therein having a microstructure with a preferred orientation of (200) crystal plane.

In addition, the flexible copper-clad laminate of the present application also has excellent thermal resistance and is expected to withstand welding and reflow steps in the manufacture process of a printed circuit board. For example, the flexible copper-clad laminate of the present application can withstand a heat treatment for at least 30 seconds or longer without blistering or delaminating at 260° C. or 288° C. or even 320° C. or a higher temperature.

### Printed Circuit Boards

The flexible copper-clad laminate of the present application may be subjected to known patterning methods such as a subtraction method (photolithography) or an addition method (electroplating) to form a predetermined conductor pattern (i.e., a circuit) on the resist side of the copper foil, thereby producing a printed circuit board (PCB), wherein the printed circuit board is a flexible printed circuit board (FPCB) or a rigid-flexible printed circuit board (RFPCB). Since the manufacture processes for FPCB and RFPCB are well known to one skilled in the art, the disclosure thereof is omitted herein for brevity.

The flexible printed circuit board or rigid-flexible printed circuit board prepared with the flexible copper-clad laminate of the present application may be assembled with other parts, such as leads or holes, to form various electronic devices. The electronic devices include computer peripheral equipments, e.g., ribbon leads for hardware driver; consumer equipments, such as a laptop computer, a tablet computer, an electronic reader, a portable game apparatus, a portable media player, a digital camera, or a mobile phone; wearable equipments; smart home equipments; healthcare equipments; electronic devices for vehicles; manned vehicles and unmanned vehicles; aeronautical facilities, e.g., unmanned aerial vehicles, planes, or aerospace equipments, etc.

Without further illustration in detail, it is believed that one skilled in the art using the preceding description can utilize the application to its fullest extent. Therefore, the following Examples should be construed as merely illustrative and not limiting the present disclosure in any manner.

### EXAMPLES

The abbreviations “E” represents “example” and “CE” represents “comparative example”, and each is followed by a number indicating that the electrodeposited copper foil was prepared or used in which example. Examples and comparative examples were prepared and tested in similar manners.

Several experiments are listed below to demonstrate the implementation effects of the present application, but the present application is not limited to the following content.

The raw materials used in the electrolytic solution, amounts and ratios thereof as well as details in treatment, etc. may be appropriately changed without exceeding the scope of the present application. Therefore, the present application should not be interpreted restrictively based on the experiments described below.

### Materials

Gelatin: purchased from Jellice Taiwan, with a catalog number of FL-FCC0.

NCP-A: a nitrogen-containing cationic polymer, obtained from DuPont Electronics, Inc. under the trade name of Copper Gleam™ T4, with a M_{w} in the range of 7,000-11,000.

NCP-B: a nitrogen-containing cationic polymer, obtained from DuPont Electronics, Inc. under the trade name of Copper Gleam™ T2, with a M_{w} in the range of 2,000-5,000.

NCP-C: a nitrogen-containing cationic polymer, obtained from DuPont Electronics, Inc. under the trade name of Copper Gleam™ T1, with a M_{w} in the range of 1,000-5,000.

NCP-D: a nitrogen-containing cationic polymer, obtained from DuPont Electronics, Inc. under the trade name of Copper Gleam™ T5, with a M_{w} in the range of 2,000-5,000.

NCP-E: a nitrogen-containing cationic polymer, obtained from DuPont Electronics, Inc. under the trade name of Copper Gleam™ T6, with a M_{w} in the range of 500-1,000.

HEC: hydroxyethyl cellulose, purchased from DAICEL Co.

Copper sulfate, sulfuric acid, hydrochloric acid, and compounds with unidentified commercial source were purchased from Sigma-Aldrich Co.

Copper foil RA1: a rolled annealed copper foil, purchased from Taishin copper & alumina technologies, Co., Ltd., with a nominal thickness of 12 μm, and a product number being RA501.

Copper foil RA2: a rolled annealed copper foil, purchased from JX metals corporation, with a nominal thickness of 12 μm, and a product number being BHM-HAV2.

Copper foil ED1: an electrodeposited copper foil, purchased from Chang Chun Petrochemical Co. Ltd., with a nominal thickness of 12 μm, and a product number being RTF2.

### Examples 1-8 and Comparative Examples 1-6

### Example 1

A base electrolytic solution was formulated, which contained 260 g/L of copper sulfate, 100 g/L of sulfuric acid, and 0.1 ppm of chloride ion as well as 0.1 ppm of gelatin as an additive. A rotary electrode instrument was used that had a titanium drum as the cathode (i.e., the negative electrode), a dimensional stable anode (DSA) plate (i.e., the positive electrode), and was equipped with a direct current power supply; the space between the cathode and the anode was filled with the electrolytic solution. An electrodeposited copper foil with a thickness of 12 μm was then formed on the surface of the titanium drum directly by electroplating for 45 seconds at a current density of 60 A/dm², a temperature of the electrolytic solution being 40° C., and a cathode rotary rate of 400 rpm. After electrodeposition was completed, the electrodeposited copper foil was taken from the titanium drum for surface treatment, i.e., soaking the electrodeposited copper foil in a copper protecting agent for 5 seconds, wherein the copper protecting agent was purchased from DuPont Electronics, Inc. under the trade name of CUPROTEC™. Thereafter, the electrodeposited copper foil was taken out and dried by blowing compressed air, and subjected to subsequent corresponding tests. The test results were shown in Table 1 and Table 2, respectively.

### Examples 2-6

The same base electrolytic solution as that in Example 1 was formulated, which comprised 260 g/L of copper sulfate, 100 g/L of sulfuric acid, 0.1 ppm of chloride ions, and 0.1 ppm of an additive; the additive used in each working example were listed in Table 1 and Table 2. Then, using the same equipment and electrodeposition conditions as those in Example 1, by electroplating at a current density of 60 A/dm², a temperature of the electrolytic solution being 40° C., and a cathode rotary rate of 400 rpm for 45 seconds, an electrodeposited copper foil with a thickness of 12 μm was formed directly on the surface of the titanium drum. After the electrodeposition was completed, the electrodeposited copper foil was removed from the titanium drum, and subjected to the same surface treatment step as that in Example 1 as well as subsequent corresponding tests. The test results were shown in Table 1 and Table 2, respectively.

### Example 7

The same base electrolytic solution as that in Example 1 was formulated, which comprised 260 g/L of copper sulfate, 100 g/L of sulfuric acid, 0.1 ppm of chloride ions, and 0.1 ppm of NCP-A as the additive. Then, using the same instrument and electrodeposition conditions as those in Example 1, by electroplating at a current density of 60 A/dm², a temperature of the electrolytic solution being 40° C., and a cathode rotary rate of 400 rpm for 780 seconds, an electrodeposited copper foil with a thickness of 210 μm was formed directly on the surface of the titanium drum. After the electrodeposition was completed, the electrodeposited copper foil was removed from the titanium drum, and subjected to the same surface treatment step as that in Example 1 as well as subsequent corresponding tests. The test results were shown in Table 1 and Table 2, respectively.

### Example 8

The same base electrolytic solution as that in Example 1 was formulated, which comprised 260 g/L of copper sulfate, 100 g/L of sulfuric acid 100 g/L, 0.1 ppm of chloride ions, and 0.1 ppm of NCP-A as the additive. Then, using the same instrument and electrodeposition conditions as those in Example 1, by electroplating at a current density of 80 A/dm², a temperature of the electrolytic solution being 40° C., and a cathode rotary rate of 400 rpm for 34 seconds, an electrodeposited copper foil with a thickness of 12 μm was formed directly on the surface of the titanium drum. After the electrodeposition was completed, the electrodeposited copper foil was removed from the titanium drum, and subjected to the same surface treatment step as that in Example 1 as well as subsequent corresponding tests. The test results were shown in Table 1 and Table 2, respectively.

### Comparative Examples 1-3

Comparative Examples 1-3 were commercially available copper foils, among which the RA copper foil of CE1 was RA1, the RA copper foil of CE2 was RA2, and the ED copper foil of CE3 was ED1. The sampling manners, the test instruments, the measurement methods and the analysis methods were the same as those specimens of Examples 1-9, and the test results were shown in Table 1 and Table 2, respectively.

### Comparative Example 4

The electrolytic solution used in this Comparative Example contained 260 g/L of copper sulfate and 100 g/L of sulfuric acid, and was free of chloride ion and additive. Then, using the same instrument and electrodeposition conditions as those in Example 1, by electroplating at a current density of 60 A/dm², a temperature of the electrolytic solution being 40° C., and a cathode rotary rate of 400 rpm for 45 seconds, an electrodeposited copper foil with a thickness of 12 μm was formed directly on the surface of the titanium drum. After the electrodeposition was completed, the electrodeposited copper foil was removed from the titanium drum, and subjected to the same surface treatment step as that in Example 1 as well as subsequent corresponding tests. The test results were shown in Table 1 and Table 2, respectively.

### Comparative Example 5

The electrolytic solution used in this Comparative example contained 260 g/L of copper sulfate, 100 g/L sulfuric acid, and 0.1 ppm chloride ions, but without additive. Then, using the same instrument and electrodeposition conditions as those in Example 1, by electroplating at a current density of 60 A/dm², a temperature of the electrolytic solution being 40° C., and a cathode rotary rate of 400 rpm for 45 seconds, an electrodeposited copper foil with a thickness of 12 μm was formed directly on the surface of the titanium drum. After the electrodeposition was completed, the electrodeposited copper foil was removed from the titanium drum, and subjected to the same surface treatment step as that in Example 1 as well as subsequent corresponding tests. The test results were shown in Table 1 and Table 2, respectively.

### Comparative Example 6

The electrolytic solution used in this Comparative Example contained 260 g/L of copper sulfate, 100 g/L of sulfuric acid, and 0.1 ppm of NCP-A as additive, but without chloride ion. Then, using the same instrument and electrodeposition conditions as those in Example 1, by electroplating at a current density of 60 A/dm², a temperature of the electrolytic solution being 40° C., and a cathode rotary rate of 400 rpm for 45 seconds, an electrodeposited copper foil with a thickness of 12 μm was formed directly on the surface of the titanium drum. After the electrodeposition was completed, the electrodeposited copper foil was removed from the titanium drum, and subjected to the same surface treatment step as that in Example 1 as well as subsequent corresponding tests. The test results were shown in Table 1 and Table 2, respectively.

Details of each test methods are illustrated as below.

### Test Methods

### XRD Analysis

Two pieces of specimens (10 cm×10 cm) were cut from the electrodeposited copper foil prepared in each example, of which one piece was maintained in untreated state (i.e., prior to heat treatment), and the other piece was subjected to a heat treatment by being placed in an oven at 200° C. (normal pressure, under air) and baked for 2 hours. XRD analysis was used to measure and calculate the grain orientation ratio and the grain size distribution of each piece of the specimen.

The to-be-tested specimen was placed with the S side facing the low background noise carrier, and diffraction data was obtained using a Bruker AXS D8 Advance X-ray diffraction instrument (at a wavelength of 1.5418 Å) equipped with a LynxEye detector under the measurement conditions of 0.025 degree for each stepping and 2 Theta angle of 40-95 degree. Background noise was subtracted from the data via an EVA software, and the calculation was performed by using the following texture coefficient (Tc(hkl)) equation with Miller indexes (111), (200), (220), (311) crystal plane diffraction intensity.

$$Tc ( hkl ) = [ I ( hkl ) / {I}_{0} ( hkl ) ] / ( 1 / N ) [ {\sum }_{N} I ( hkl ) / {I}_{0} ( hkl ) ]$$

(Tc: texture coefficient; I: diffraction intensity of the sample with respect to a (hkl) surface; I₀: reference diffraction intensity; N: number of Miller Indexes, reference material diffraction intensity (I₀)). Obtaining Tc(111), Tc(200), Tc(220), Tc(311), using the sum of each Tc(hkl) as the denominator and each Tc(hkl) as the numerator and multiplying by 100, the grain orientation ratio of the sample in each crystal plane was obtained, and the results for each Example and each Comparative Example were recorded in Table 1.

### EBSD Analysis

Two pieces of specimens (10 cm×10 cm) were cut from the electrodeposited copper foil prepared in each example, of which one piece was maintained in untreated state (i.e., prior to heat treatment), and the other piece was subjected to a heat treatment by being placed in an oven at 200° C. (normal pressure, under air) and baked for 2 hours. EBSD analysis was used to measure, and the obtained data was analyzed by a software to provide the values of average grain sizes, twin grain boundary ratios and grain orientation ratios.

The EBSD specimen was prepared by polishing firstly with an ion milling cross-section polishing machine, placed in an SEM (JEOL-IT800SHL) cavity with a 50-degree pre-tilted bracket, and then tilted the stage by 20 degree. The acceleration voltage was set at 15-20 kV using the high current mode. EBSD data was collected with an Oxford Symmetric EBSD detector. The EBSD data collection parameters were set as follows: 3000× magnification, and the acquisition step size was 0.1 μm.

For grain size analysis, loading the EBSD data into AZtecCrystal software, and setting the special grain boundaries to copper phase, crystal axis/angle of <111> 60°, a deviation angle of 5°. The grain sizes (equivalent circle diameter, ECD) and grain distribution were output automatically by the software. Equivalent Circle Diameter was selected for calculating the average grain size, and grains with a size less than 0.5 μm were considered as errors caused by scanning and were excluded from calculation, the average grain size was obtained. The results of each Example and each Comparative Example were recorded in Table 2.

For twin grain boundary ratio analysis, the EBSD data was loaded to AZtecCrystal software, and the output was selected as BandContrast+special grain boundary diagram. The parameters for the special grain boundary diagram were set as follows: minimum angle of 10°, copper phase, crystal axis/angle of <111>/60°, and a deviation angle of 1°. The twin grain boundary ratios of each Example and each Comparative Example were recorded in Table 2.

For grain orientation ratios in the {001} crystal plane family, loading the EBSD data into AZtecCrystal software, analyzing the texture component, and selecting the output to be the grain orientation ratios and an inverse pole figure of the {001} crystal plane. Because the specimen was a cross-sectional sample, the 001//ND was set as 001 direction in parallel to the Y1 direction (defined as red color), 101//ND was set as 101 direction in parallel to the Y1 direction (defined as green color), and 111//ND was set as 111 direction in parallel to the Y1 direction (defined as blue color). A deviation angle was set to be 20° to obtain more area ratios. The results of each Example and each Comparative Example were recorded in Table 1.

### Thickness of Copper Foils

According to the standard method of IPC-TM-650 2.2.12, a copper foil prior to heat treatment was cut and subjected to copper foil thickness measurement by a weighing method.

### Surface Roughness

The M side of a copper foil sample prior to heat treatment was inspected at 5 regions by using a laser scanning microscope (manufactured by Olympus, Model No. OLS-5000) at a 100× objective magnification and without any cut-off filter. According to the ISO25178 method, the roughness was measured at various spots, and the measured data were averaged. Sz is defined as the sum of top 10 maximum peak heights and top 10 maximum valley depths in a defined region.

### Elongation and Tensile Strength

Two pieces of specimens (5 cm×15 cm) were cut from the electrodeposited copper foil prepared or used in each example, of which one piece was maintained in untreated state (i.e., prior to heat treatment), and the other piece was subjected to a heat treatment by being placed in an oven at 200° C. (normal pressure, under air) and baked for 2 hours. The two specimens were measured at ambient temperature by using a tensile tester (SHIMADZU, Model No. AGS-X) for the tensile strength and elongation according to the method of IPC-TM-650 2.4.18B. The results of each Example and each Comparative Example were recorded in Table 2.

TABLE 1

| | | | | | | | | EBSD |
|---|---|---|---|---|---|---|---|---|
| | Amount of Cl⁻/ | | Copper | | | | | grain |
| | Additive in | Heat | foil | XRD grain | | | | orientation |
| | electrolyte | treated* | thickness | orientation ratio* | | | | ratio |
| No. | (ppm) | (Y/N) | (μm) | (111) | (200) | (220) | (311) | {001} |
| CE1 | RA1 - | N | 11.44 | 3.53 | 28.63 | 56.54 | 11.30 | 17.30 |
| | irrelevant | Y | | 2.83 | 66.18 | 15.65 | 15.34 | 35.60 |
| CE2 | RA2 - | N | 11.77 | 0.59 | 5.88 | 89.47 | 4.06 | 3.31 |
| | irrelevant | Y | | 0.07 | 99.76 | 0.12 | 0.05 | 93.75 |
| CE3 | ED1 - not | N | 11.52 | 4.66 | 4.43 | 83.84 | 7.07 | 2.41 |
| | disclosed | Y | | 7.70 | 8.51 | 52.65 | 31.14 | 5.33 |
| CE4 | Cl⁻ (0) / | N | 11.56 | 50.09 | 15.43 | 9.51 | 24.98 | 15.99 |
| | Additive (0) | Y | | 29.75 | 48.12 | 13.73 | 8.40 | 19.73 |
| CE5 | Cl⁻ (0.1) / | N | 11.58 | 56.55 | 8.19 | 8.15 | 27.11 | 5.75 |
| | Additive (0) | Y | | 29.63 | 43.45 | 20.48 | 6.44 | 18.77 |
| CE6 | Cl⁻ (0) / | N | 11.58 | 47.06 | 18.87 | 10.67 | 23.41 | 10.84 |
| | NCP-A (0.1) | Y | | 25.17 | 45.22 | 17.46 | 12.15 | 17.98 |
| E1 | Cl⁻ (0.1) / | N | 11.59 | 60.14 | 19.03 | 8.49 | 12.34 | 15.30 |
| | Gelatin (0.1) | Y | | 23.27 | 69.77 | 3.79 | 3.17 | 33.45 |
| E2 | Cl⁻ (0.1)/ | N | 11.54 | 62.61 | 17.52 | 4.16 | 15.71 | 13.57 |
| | NCP-A (0.1) | Y | | 22.90 | 70.50 | 3.94 | 2.66 | 31.05 |
| E3 | Cl⁻ (0.1) / | N | 11.57 | 69.13 | 11.99 | 3.74 | 15.14 | 13.85 |
| | NCP-B (0.1) | Y | | 21.63 | 72.87 | 2.90 | 2.60 | 25.75 |
| E4 | Cl⁻ (0.1) / | N | 11.61 | 58.12 | 18.95 | 8.79 | 14.14 | 15.30 |
| | NCP-C (0.1) | Y | | 23.27 | 67.48 | 6.06 | 3.19 | 30.25 |
| E5 | Cl⁻ (0.1) / | N | 11.59 | 73.96 | 15.20 | 8.29 | 2.73 | 15.20 |
| | NCP-E (0.1) | Y | | 17.72 | 78.48 | 1.83 | 1.97 | 27.40 |
| E6 | Cl⁻ (0.1) / | N | 11.57 | 62.90 | 15.98 | 4.36 | 18.76 | 16.45 |
| | HEC (0.1) | Y | | 25.63 | 64.84 | 5.56 | 3.97 | 38.35 |
| E7 | Cl⁻ (0.1) / | N | 208.54 | 72.78 | 12.82 | 10.39 | 4.01 | 17.64 |
| | NCP-A (0.1) | Y | | 10.78 | 59.89 | 21.04 | 8.3 | 21.42 |
| E8 | Cl⁻ (0.1) / | N | 11.62 | 57.11 | 8.40 | 8.38 | 26.10 | 6.49 |
| | NCP-A (0.1) | Y | | 12.30 | 67.16 | 12.89 | 7.64 | 24.56 |

*“N” represents “prior to heat treatment”, and “Y” represents “after heat treatment”.
*The grain orientation ratio value was bolded to indicate it's the preferred orientation of the copper foil after heat treatment.

It can be seen from the XRD grain orientation distribution ratio data in Table 1, the RA copper foils of CE1 and CE2 each had a preferred orientation of (220) crystal plane prior to heat treatment, a preferred orientation of (200) crystal plane after heat treatment, and the grain orientation ratio on the (200) crystal plane being 66% and 99% or more, respectively. The commercially available electrodeposited copper foil in CE3 had a preferred orientation of (220) crystal plane before and after heat treatment. The electrodeposited copper foils of CE4, CE5 and CE6 each had a preferred orientation of (200) crystal plane after heat treatment, but the grain orientation ratios on the (200) crystal plane of these examples were less than 50%. In contrast, the ED copper foils of E1-E8, each was one embodiment of the present electrodeposited copper foils, had a preferred orientation of (200) crystal plane after heat treatment and the respective grain orientation ratio on the (200) crystal plane was 50% or more. It can be seen that the electrodeposited copper foils of the present application after heat treatment have a preferred orientation similar to that of a RA copper foil and a grain orientation ratios on the (200) crystal plane being 50% or more.

It can be seen from EBSD grain orientation data of Table 1 that the RA copper foils of CE1 and CE2, after heat treatment, had grain orientation ratios on the {001} crystal plane family being 20% or more. The ED copper foils of CE3-CE6, after heat treatment, had grain orientation ratios on the {001} crystal plane family being less than 20%. In contrast, the ED copper foils of E1-E8, after heat treatment, had grain orientation ratios on the {001} crystal plane family being 20% or more.

In conclusion, the present electrodeposited copper foil after heat treatment has a preferred orientation of (200) crystal plane similar to that of a RA copper foil; it has a grain orientation ratio of 50% or more on the (200) crystal plane as measured by XRD analysis; and a grain orientation ratio of 20% or more on the {001} crystal plane family as measured by EBSD analysis.

TABLE 2

| | | | | | Average | Twin grain | | |
|---|---|---|---|---|---|---|---|---|
| | Amount of Cl⁻/ | Heat | | | grain | boundary | | Tensile |
| | Additive | treated* | Sz | Conductivity | size | ratio | Elongation | strength |
| No. | (ppm) | (Y/N) | (μm) | (×10⁶ S/m) | (μm) | (%) | (%) | (Kgf/mm²) |
| CE1 | RA1 - | N | 2.84 | | 1.89 | 8.16 | 1.07 | 44.7 |
| | irrelevant | Y | | 58.51 | 4.56 | 76.40 | 3.56 | 13.8 |
| CE2 | RA2 - | N | 2.01 | | 0.98 | 1.50 | 2.20 | 50.4 |
| | irrelevant | Y | | 57.43 | 3.52 | 39.63 | 2.43 | 10.9 |
| CE3 | ED1 - not | N | 3.41 | | 1.57 | 40.71 | 2.56 | 37.1 |
| | disclosed | Y | | 55.20 | 1.95 | 57.60 | 6.13 | 27.9 |
| CE4 | Cl⁻ (0) / | N | 2.03 | | 1.20 | 28.73 | 3.40 | 62.2 |
| | Additive (0) | Y | | 57.21 | 3.58 | 48.12 | 15.10 | 24.0 |
| CE5 | Cl⁻ (0.1)/ | N | 2.58 | | 1.24 | 29.12 | 3.30 | 60.9 |
| | Additive (0) | Y | | 56.95 | 3.85 | 72.87 | 13.10 | 24.2 |
| CE6 | Cl⁻ (0) / | N | 2.01 | | 1.24 | 32.33 | 3.50 | 61.2 |
| | NCP-A (0.1) | Y | | 56.45 | 3.95 | 72.43 | 13.90 | 24.9 |
| E1 | Cl⁻ (0.1) / | N | 2.43 | | 0.86 | 26.40 | 3.84 | 60.4 |
| | Gelatin (0.1) | Y | | 57.55 | 2.69 | 69.47 | 7.11 | 22.4 |
| E2 | Cl⁻ (0.1)/ | N | 2.56 | | 0.88 | 25.87 | 3.89 | 61.3 |
| | NCP-A (0.1) | Y | | 57.13 | 2.49 | 64.13 | 6.83 | 22.1 |
| E3 | Cl⁻ (0.1)/ | N | 2.13 | | 0.83 | 25.86 | 3.95 | 62.1 |
| | NCP-B (0.1) | Y | | 57.36 | 2.12 | 63.37 | 7.71 | 22.3 |
| E4 | Cl⁻ (0.1) / | N | 2.01 | | 0.84 | 27.47 | 4.27 | 61.4 |
| | NCP-C (0.1) | Y | | 57.33 | 2.79 | 57.37 | 7.17 | 22.2 |
| E5 | Cl⁻ (0.1) / | N | 2.18 | | 0.89 | 27.50 | 4.04 | 59.3 |
| | NCP-E (0.1) | Y | | 57.27 | 3.96 | 63.85 | 7.82 | 22.2 |
| E6 | Cl⁻ (0.1) / | N | 2.14 | | 0.86 | 26.25 | 4.00 | 61.4 |
| | HEC (0.1) | Y | | 57.16 | 3.35 | 64.33 | 7.27 | 22.3 |
| E7 | Cl⁻ (0.1) / | N | 2.78 | | 0.93 | 24.56 | 3.51 | 60.0 |
| | NCP-A (0.1) | Y | | 58.69 | 4.56 | 67.60 | 9.31 | 24.5 |
| E8 | Cl⁻ (0.1) / | N | 2.11 | | 0.91 | 27.17 | 4.20 | 62.3 |
| | NCP-A (0.1) | Y | | 57.67 | 3.97 | 72.40 | 13.60 | 22.4 |

* “N” represents “prior to heat treatment”, and “Y” represents “after heat treatment”.

It can be seen from the surface roughness (Sz) data in Table 2, the ED copper foils of E1-E8 each had a surface roughness (Sz) on the M side being 3.0 μm or less prior to heat treatment. Additionally, comparing the conductivity data of E1-E8 with that of CE3, the ED copper foils of E1-E8 after heat treatment, each had a conductivity of 57.0×10⁶ S/m or more; said conductivity was better than that of the commercially available ED copper foil of CE3 (55.20×10⁶ S/m), and was comparable to that of the RA copper foil of CE2.

It can be seen from the data in Table 2, the ED copper foils of E1-E8 each had an average grain size of less than 1.0 μm prior to the heat treatment; and the average grain size increased to 2.0 μm or more after heat treatment. In addition, the ED copper foils of E1-E8 each had a twin grain boundary ratio of 30% or less prior to the heat treatment; and the twin grain boundary ratio increased to 50% or more after heat treatment. Further, it can be seen from the data in Table 2, the ED copper foils of E1-E8 after heat treatment each had an elongation of 5% or more and a tensile strength of 15 Kgf/mm² to 25 Kgf/mm².

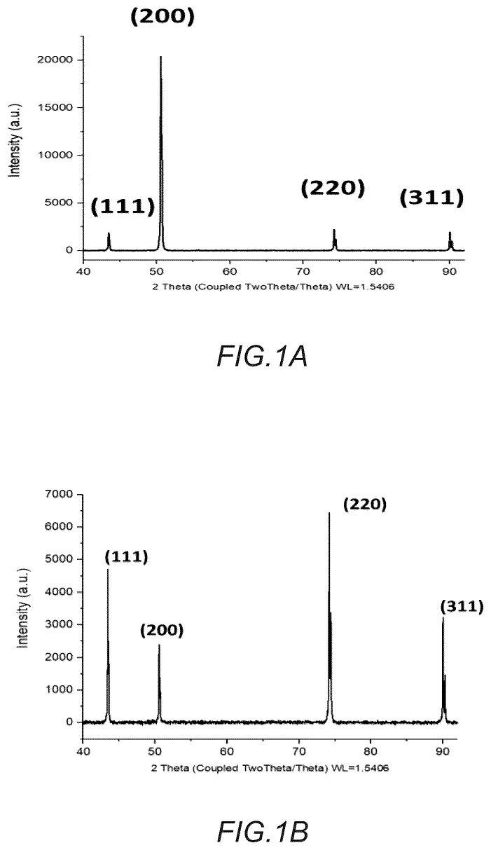

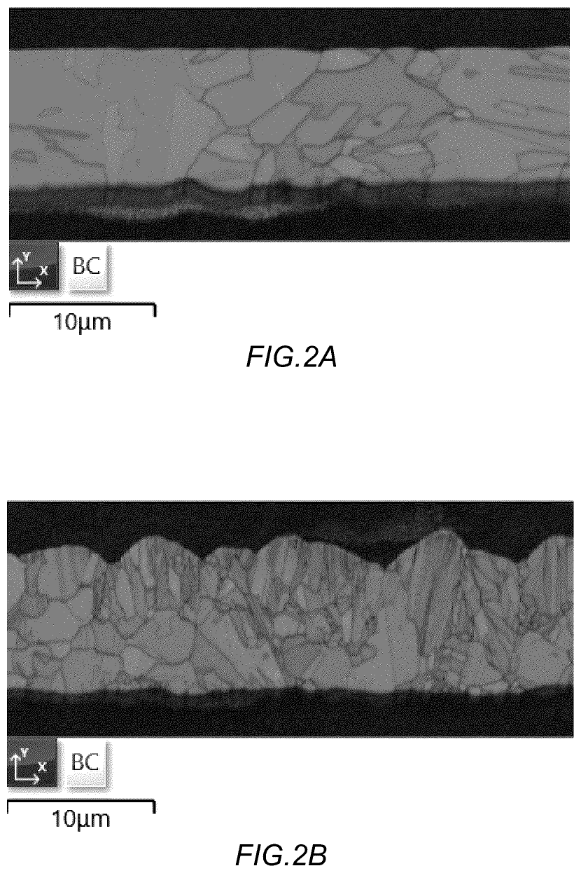

In general, RA copper foil has a grain arrangement with a preferred orientation likely to be on the (200) crystal plane, and its grains obviously grew to more than 2.0 μm in size, with reference to FIG. 1A and FIG. 2A. FIG. 1A is a graph showing the grain orientation distribution of a RA copper foil after being heated at 200° C. for 2 hours that is the specimen of Comparative Example 1 of the present application. It can be clearly seen from FIG. 1A, the RA copper foil has a grain arrangement with a preferred orientation of (200) crystal plane. FIG. 2A is an EBSD photograph showing the grain sizes of the specimen of Comparative Example 1. It can be clearly seen from the photograph of FIG. 2A and the reference scale thereof, the RA copper foil has an average grain size of more than 2.0 μm, with an actual measured average grain size being 4.56 μm.

In contrast, the ED copper foil is generally produced by electroplating at a high current density, e.g., a direct current above 50 ASD to achieve industrial mass production.

However, under the condition of a high current density, copper atoms in the copper deposition layer grow easily along the loosely arranged (220) crystal plane and/or (311) crystal plane. Even after heat treatment, the electrodeposited copper foil has a grain arrangement with a preferred orientation mainly on the (111) crystal plane and/or the (220) crystal plane rather than on the (200) crystal plane, and has a relative smaller grain size that is generally less than 2.0 μm, with reference to FIG. 1B and FIG. 2B, that are the specimen of Comparative Example 3 of the present application.

Additionally, directional imaging inverse pole figures (abbreviated as inverse pole figures or IPFs hereinafter) of the cross-sections of the RA copper foil specimen of Comparative Example 1 and the ED copper foil specimen of Comparative Example 3 obtained by EBSD analysis were obtained. When comparing the grain size and grain orientation distribution between the RA copper foil and the ED copper foil, the same conclusion may be drawn that the RA copper foil has a grain size obviously larger than that of the ED copper foil. Furthermore, the inverse pole figure of the RA copper foil specimen shows that the predominant grain orientation is the {001} crystal plane family which comprises all crystallographically equivalent crystal planes, i.e., comprises the crystal planes of (001), (100), and (010), etc.; and the inverse pole figure of the ED copper foil specimen shows that the predominant grain orientation is the {101} crystal plane family which comprises the crystal planes of (101), (011), and (110), etc.

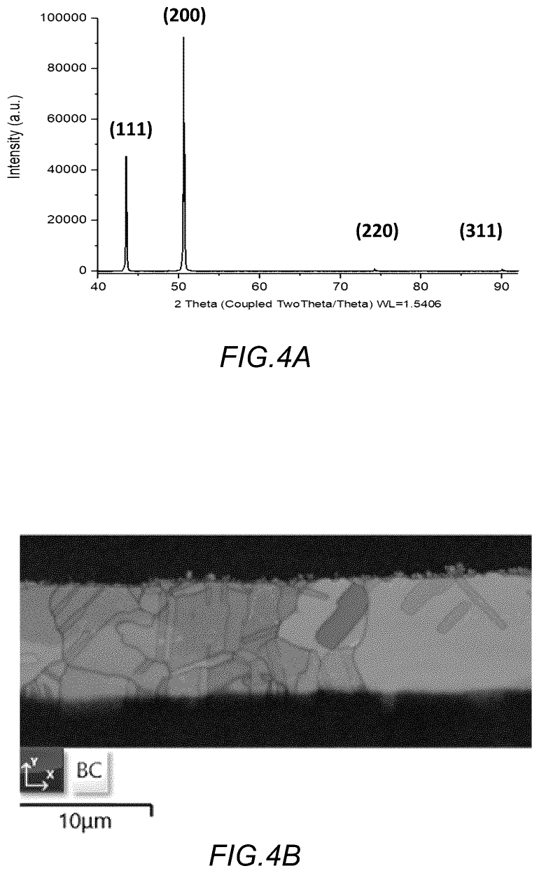

FIGS. 4A and 4B, respectively, show the grain orientation distribution graph obtained by XRD analysis of an embodiment of the present ED copper foil, and the grain size photograph of the cross-section of the copper foil obtained by EBSD analysis. The ED copper foil is a specimen of Example 6 of the present application. Unlike the more conventional ED copper foil of Comparative Example 3, this ED copper foil has a grain arrangement with a preferred orientation of (200) crystal plane and a much larger grain size. An inverse pole figure of the ED copper foil of Example 6 shows that the predominant grain orientation is the {001} crystal plane family, much like the RA copper foil specimen of Comparative Example 1.

While the application has been illustrated and described in typical embodiments, it is not intended to be limited to the details shown, since various modifications and substitutions are possible without departing from the spirit of the application. As such, modifications and equivalents of the application herein disclosed may occur to persons skilled in the art using no more than routine experimentation, and all such modifications and equivalents are believed to be within the spirit and scope of the application as defined by the following claims.

What is claimed is:

1. An electrodeposited copper foil with a preferred orientation of (200) crystal plane after heat treatment, wherein
the electrodeposited copper foil prior to heat treatment has a grain orientation ratio of 20% or less on the (200) crystal plane as determined by XRD analysis, and a grain orientation ratio of less than 20% on the {001} crystal plane family as determined by EBSD analysis;
the electrodeposited copper foil after heat treatment has a grain orientation ratio of 50% or more on the (200) crystal plane as determined by XRD analysis, and a grain orientation ratio of 20% or more on the {001} crystal plane family as determined by EBSD analysis; and
the heat treatment is conducted by heating at 200° C. for 2 hours.

2. The electrodeposited copper foil of claim 1, wherein
the electrodeposited copper foil prior to heat treatment has an average grain size of less than 1.0 μm, and a twin grain boundary ratio of 30% or less;
the electrodeposited copper foil after heat treatment has an average grain size of 2.0 μm or more and a twin grain boundary ratio of 50% or more; and
the average grain size and twin grain boundary ratio are determined by EBSD analysis.

3. The electrodeposited copper foil of claim 1, wherein the electrodeposited copper foil has a thickness of 3.0 μm to 300 μm.

4. The electrodeposited copper foil of claim 1, wherein the electrodeposited copper foil prior to heat treatment has a surface roughness (Sz) of 3.0 μm or less on the M side.

5. The electrodeposited copper foil of claim 1, wherein the electrolytic copper foil after heat treatment has an electrical conductivity of 57.0×10⁶ S/m or more.

6. The electrodeposited copper foil of claim 1, wherein
the electrodeposited copper foil prior to heat treatment has an elongation of less than 5%; and
the electrodeposited copper foil after heat treatment has an elongation of 5% or more, and a tensile strength of 15 Kgf/mm² to 25 Kgf/mm².

7. A method for manufacturing an electrodeposited copper foil of claim 1, comprising:
i) providing an electrolytic solution at a temperature of 20° C. to 55° C. in an electrolytic cell;
ii) applying an electric current at a current density of 30 A/dm² to 100 A/dm² to an anode plate and a rotating cathode drum that are spaced apart from each other in the electrolytic solution;
iii) obtaining a copper foil on the rotating cathode drum by electrodeposition; and
iv) separating the copper foil obtained from step iii);
wherein
the electrolytic solution comprises:
120 g/L to 450 g/L of copper sulfate;
30 g/L to 140 g/L of sulfuric acid;
0.01 ppm to 5.00 ppm of chloride ion; and
0.01 ppm to 2.50 ppm of at least one additive.

8. The method of claim 7, wherein the additive comprises gelatin, animal glue, cellulose, nitrogen-containing cationic polymer, or a combination thereof.

9. The method of claim 7, wherein the additive is a nitrogen-containing cationic polymer, and the nitrogen-containing cationic polymer has a weight-average molecular weight of from 500 g/mole to 12,000 g/mole.

10. The method of claim 9, wherein the nitrogen-containing cationic polymer is a reaction product of a diamine of formula (I) or an imidazole of Formula (II) with an epoxide of Formula (III) or a diepoxide of Formula (IV) in 1:1 molar ratio: 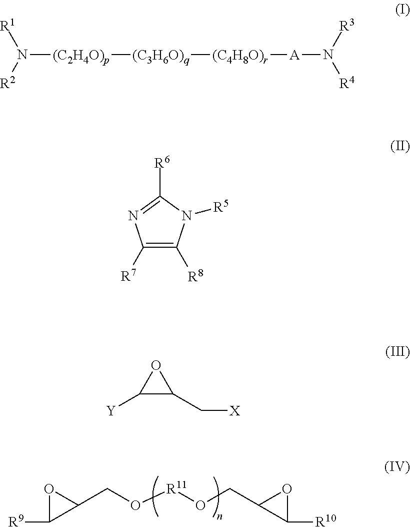
wherein
each of R¹, R², R³, and R⁴ is independently H or C₁-C₃ alkyl;
each of R⁵, R⁶, R⁷, and R⁸ is independently H or C₁-C₆alkyl, and R⁷ and R⁸ are optionally linked to each other to form a saturated ring;
R⁹ and R¹⁰ are each independently H or C₁-C₄ alkyl;
R¹¹ is a divalent linking group selected from C₂-C₈ alkylene, C₅-C₁₀ cycloalkylene, and C₁-C₄ alkylene-C₅-C₁₀ cycloalkylene, where R¹¹ is optionally substituted with C₁-C₄ alkyl or —OH;
A is a divalent linking group selected from C₂-C₈ alkylene, C₅-C₁₀ cycloalkylene, C₁-C₄ alkylene-C₅-C₁₀ cycloalkylene-C₁-C₄ alkylene, C₆-C₂₀ arylene, and C₁-C₄ alkylene-C₆-C₂₀ arylene-C₁-C₄ alkylene, and where A is optionally substituted with C₁-C₄ alkyl or —OH;
Y is H or C₁-C₄ alkyl;
X is halogen;
each of p, q, and r is independently an integer of 0 to 10; and
n is an integer from 1 to 20.

11. A flexible copper-clad laminate, comprising:
the electrodeposited copper foil of claim 1, and
a dielectric layer provided on at least one surface of the electrodeposited copper foil,
wherein
the electrodeposited copper foil has a grain orientation ratio of 50% or more on the (200) crystal plane as determined by XRD analysis, and a grain orientation ratio of 20% or more on the {001} crystal plane family as determined by EBSD analysis;
the dielectric layer has a thickness of 5 μm to 100 μm; and
the dielectric layer is composed of at least one layer of a polymeric material having a thermal decomposition temperature (1%) of 260° C. or higher.

12. The flexible copper-clad laminate of claim 11, wherein the polymeric material is polyimide, liquid crystal polymer, or fluorine-based polymer.

13. A method for manufacturing the flexible copper-clad laminate of claim 11, comprising:
providing the electrodeposited copper foil of claim 1, and
coating or laminating at least one layer of a polymeric material or a precursor thereof to form a dielectric layer on at least one surface of the electrodeposited copper foil.

14. A printed circuit board, that is manufactured from the flexible copper-clad laminate of claim 11, wherein the printed circuit board is a flexible printed circuit board (FPCB) or a flexible-rigid printed circuit board (FRPCB).

15. An electronic device, comprising the printed circuit of claim 14.
